(19) United States
(12) Patent Application Publication
(10) Pub. No.: US 2005/0225312 A1
(43) Pub. Date: Oct. 13, 2005

(54) Galvanometer

(76) Inventors: William Daly, Brookline, NH (US); Brian Stokes, Windham, NH (US); Rolland Zeleny, Sharon, MA (US)

Correspondence Address: GROSSMAN, TUCKER, PERREAULT & PFLEGER, PLLC, 55 SOUTH COMMERICAL STREET, MANCHESTER, NH, 03101, US

(21) Appl. No.: 10/822,486

(22) Filed: Apr. 12, 2004

(51) Int. Cl. G01R 1/20

(52) U.S. Cl. 324/146

(57) ABSTRACT

In one embodiment, a galvanometer may include a moving magnet rotor. The moving magnet rotor may include an opening in each end. An output shaft and a tail shaft may be received in respective opening in the moving magnet rotor. The output shaft and tail shaft may formed from a material having a high stiffness to strength ratio, such as a ceramic material.

### FIELD

This disclosure relates generally to torque motors, and more particularly relates to galvanometers.

### BACKGROUND

A galvanometer unit may include a limited-rotation electro magnetic motor having a permanent-magnet that interacts with the fields generated by a flowing electric current. Torque motors of this type are widely used for a variety of application. One application of torque motors is the use in scanners, for example in laser marking systems and the like. A scanner may include an optical element, such as a mirror, that is attached to an output shaft of the galvanometer. Reciprocal rotation of the motor may cause a light beam directed at the mirror to sweep back and forth over a target surface. This type of device is often called an optical scanning galvanometer or optical scanner.

There are three basic types of torque motors that are typically used in optical scanning applications. These include a moving coil design, a moving iron pole construction, and a moving magnet type. With the introduction of high energy or rare earth permanent magnets, the moving magnet type has become the preferred type of torque motor for optical scanners.

Since the torque motor undergoes limited rotation, the rotor may be mounted on a flexural pivot that acts as a torsional spring for motor rotation. Alternatively, the motor may incorporate bearings to support the rotor and the limitation on rotation may be provided by the servo system that controls the angular position of the mirror. In order to insure proper operation of the galvanometer, and to prevent premature failure of the bearings and/or galvanometer, the bearings must be carefully adjusted.

The performance of the torque motor may also be related to the torsional resonance of the rotating system, i.e., the rotor, the shafts, the load, e.g. the optical element, and any other rotating components. A position sensor may be coupled to a shaft of the galvanometer to provide position feedback in a servo loop, and the output of the sensor may include components resulting from resonant twisting of the shaft. There are several resonance modes and the pass band of the servo system must be well below the lowest resonance frequency to avoid unwanted feedback, which may cause instability of the servo system. Therefore, the higher the natural resonance of the motor, the more stable the servo system may be.

### BRIEF DESCRIPTION OF THE DRAWINGS

Features and advantages of embodiments of the claimed subject matter will become apparent from the following Detailed Description, which description should be considered in conjunction with the accompanying drawings, wherein:

FIG. 1 is a schematic view of a scanning system employing a galvanometer;

FIG. 2 illustrates an embodiment of a galvanometer in cross-section;

FIG. 3 is a cross-sectional view of an embodiment of a rotor consistent with the present disclosure;

FIG. 4 is a bottom perspective view of a galvanometer showing an embodiment of a mechanical stop arrangement;

FIG. 5 is a perspective view of an embodiment of a galvanometer rotor and a diaphragm spring for a galvanometer;

FIG. 6 is a schematic illustration of a galvanometer utilizing a diaphragm spring to preload a bearing;

FIG. 7 schematically illustrates the galvanometer of FIG. 6 with the bearing preloaded by the diaphragm spring; and

FIG. 8 shows the diaphragm spring of FIG. 5 in plan view.

### DETAILED DESCRIPTION

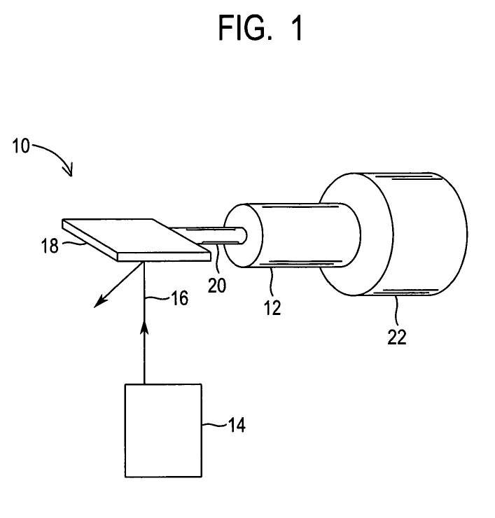

Referring to FIG. 1, a scanning system 10 is illustrated including a moving magnet galvanometer 12 according to the present disclosure. In the illustrated application the galvanometer 12 is part of a larger optical scanning system. This is, however, just one application of the galvanometer 12 consistent with the present disclosure. A galvanometer 12 according to the present disclosure may be used in a wide variety of applications. Accordingly, the galvanometer 12 disclosed herein should not be construed as being limited to any particular application.

The illustrated scanning system 10 includes a light source 14 providing light 16. The light 16 may be directed to an optical element 18. The optical element 18 may be, for example, a lens, mirror, wave plate, or the like used to reflect light 16 from the light source 14. The optical element 18 may be coupled to the output shaft 20 of the galvanometer 12. The optical element 18 may be either directly or indirectly coupled to said output shaft 20. The galvanometer 12 may be energized to steer the beam of light 16 by rotating the optical element 18 about the axis of the output shaft 20. The movement of the output shaft 20, and thereby the movement of the optical element 18, may be measured by position sensor 22. An output from the position sensor 22 may be employed in a feedback control system to compare and correct a measured position of the galvanometer output shaft 20 with the desired position of the output shaft 20.

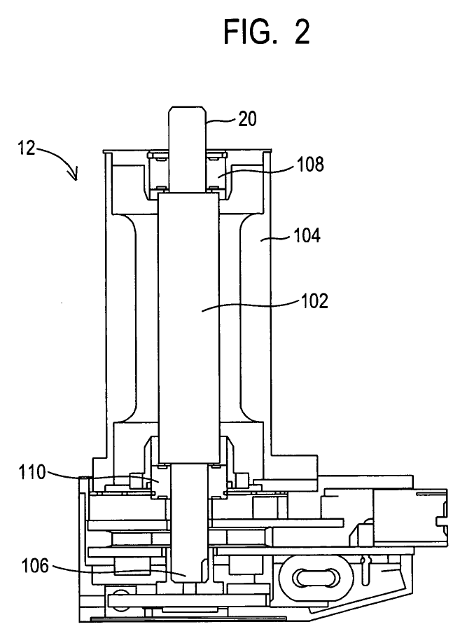

Turning to FIG. 2, an embodiment of a moving magnet galvanometer 12 consistent with the present disclosure is shown in a schematic cross-sectional view. The galvanometer 12 is shown including a rotor 102 and a stator 104. The rotor 102 may comprise a magnet including an output shaft 20 and tail shaft 106. The magnet may be either a permanent magnet or an electromagnet. The magnet according to one embodiment may be a permanent magnet longitudinally magnetized such that the rotor 102 includes generally semi-cylindrical north and south poles. A rare earth type of permanent magnet may be utilized that is made of samarium cobalt or neodymium or the like. Various other varieties of magnets may also suitably be employed in a galvanometer 12 herein.

The stator 104 may include coils and a magnetically permeable housing. The rotor 102 may be disposed inside, or surrounded by, the stator 104, with the output shaft 20 and tail shaft 106 protruding therefrom. As shown in the illustrated embodiment, the rotor 102 may be supported at each end by bushings, bearings 108, 110, or the like. The bearings 108, 110 may be carried on the output shaft 20 and tail shaft 106.

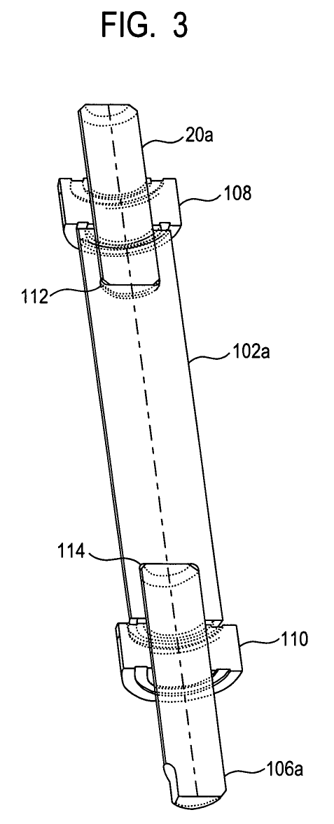

A cross-sectional view of an embodiment of a rotor 102a suitable for use in a galvanometer consistent with the present disclosure is shown in FIG. 3. As previously mentioned, a rotor 102a may include an output shaft 20a and a tail shaft 106a. Consistent with this embodiment, the output shaft 20a and/or the tail shaft 106a may be directly coupled to the rotor 102a. An end of the rotor 102a may include an opening 112 therein. At least a portion of the output shaft 20a may be received in the opening 112, with the remainder of the output shaft 20a extending from the rotor 102a. The tail shaft 106a of the rotor 102a may be similarly configured. The rotor 102a may include an opening 114 in the other end of the rotor 102a. As with the output shaft 20a, at least a portion of the tail shaft 106a may be in the opening 114 with the remainder of the tail shaft 106a extending from the rotor 102a.

The output shaft 20a and/or the tail shaft 106a may be rotationally fixed to the rotor 102a, thereby allowing torque imparted on the rotor 102a to be transmitted via the output shaft 20a and/or the tail shaft 106a. The output shaft 20a and/or tail shaft 106a may also be axially fixed to the rotor 102a. In one embodiment, the output shaft 20a may be bonded in the opening 112, for example using an adhesive such as epoxy. The adhesive may be selected to provide minimal compliance, in order to reduce losses and/or inaccuracies resulting from compliance in the adhesive. Mechanical features, such as spline featured, flatted surfaces, keyways, polygonal openings and shaft geometries, etc. may also be used to rotationally fix the output shaft 20a to the rotor 102a. According to a further embodiment, the output shaft 20a may be brazed in the opening 112. If the output shaft 20a is formed from a non-metallic material, a portion of the output shaft 20a may be metallized, thereby allowing the output shaft 20a to be brazed to the rotor 102a. Numerous other techniques may suitably be employed for rotationally fixing the output shaft 20a to the rotor 102a, including, for example, combinations and variations of the preceding examples.

The various foregoing techniques described for fixing the output shaft 20a to the rotor 102a may also suitably be employed for fixing the tail shaft 106a to the rotor 102a in embodiments in which the tail shaft 106a and output shaft 20a are each at least partially received in and extend from respective openings in the rotor 102a. However, it is not necessary that the same technique be employed for fixing both the tail shaft 106a and the output shaft 20a to the rotor 102a.

In the illustrated embodiment, the openings 112, 114 are shown generally as blind holes having a circular bore extending inwardly along the axis of the rotor 102a. Other geometries and configurations may suitably be employed consistent with the present disclosure. For example, as discussed above, one or both of the openings 112, 114 may include spline features, flatted surfaces, a keyway, or be configured having a polygonal cross-section. Various other geometries and configurations may suitably be employed in providing openings 112, 114 in the rotor 102a according to the present disclosure. Furthermore, while the embodiment depicted in FIG. 3 shows the output shaft 20a and tail shaft 106a extending to the bottom of the respective openings 112, 114 such a configuration is also not necessary.

According to one embodiment, the output shaft 20a and/or the tail shaft 106a may be formed from a ceramic material. A ceramic material may provide a relatively high stiffness to weight ratio, for example as compared to some metallic materials. Reducing the weight of the output shaft 20a and/or the tail shaft 106a may also reduce the inertia associated with the galvanometer. Reduced inertia may allow more precise movement control and quicker response from the galvanometer. Similarly, increasing the stiffness of the output shaft 20a and/or the tail shaft 106a may increase the natural resonance frequency of the galvanometer. In an embodiment in which a galvanometer according to the above embodiment is employed in a scanning system, the combination of reduced inertia and increased stiffness may allow for faster scanning and an increase in scanning bandwidth.

Additionally, ceramic materials may generally be non-conductive. Accordingly, the rotor 102a may be electrically isolated from other components of the galvanometer. Similarly, components on opposed ends of the rotor 102a may be electrically isolated from one another by the non-conductive output shaft 20a and/or tail shaft 106a. Furthermore, the non-conductive aspect of ceramic materials may allow components in contact with the either the output shaft 20a or the tail shaft 106a to be electrically isolated from each other.

Consistent with the present disclosure, the output shaft 20a and/or tail shaft 106a may be formed from materials other than ceramics. For example, various metal and metal alloys, such as steel, magnesium, titanium, etc. as well as various composite materials including metal matrix composites, ceramic matrix composites, and polymeric matrix composites may be used to produce an output shaft 20a and/or tail shaft 106a suitable for use herein. Additional materials may also suitably be employed for producing an output shaft 20a and/or a tail shaft 106a according to the disclosure.

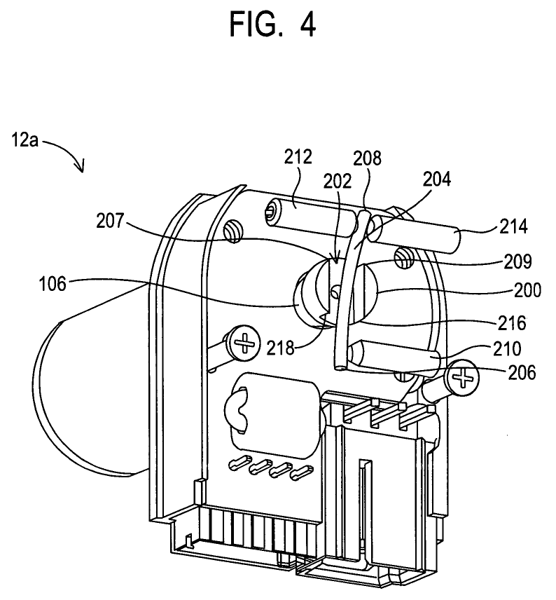

Turning to FIG. 4, an embodiment of a galvanometer 12a is shown in bottom perspective. Portions of the bottom housing and assembly of the galvanometer 12a have been omitted from the illustration to more clearly show an embodiment of a mechanical stop arrangement for limiting or controlling the range of rotational motion of the rotor (not shown). The range of motion of the galvanometer, i.e. the range of motion of the rotor, may be restricted, for example, to avoid a collision between an optical element disposed on an output shaft (not shown) of the galvanometer 12a with another optical element, a housing, etc. as may occur from an over rotation of the rotor.

As illustrated, a galvanometer 12a may include a tail shaft 106 including a tail cap 200. The tail cap 200 may define a slot 202 therein. The slot 202 may generally extend into the end of the tail cap 200. In the illustrated embodiment the slot 202 is generally centered about the longitudinal axis of the rotor, that is, the center line of the slot 202 may pass through the longitudinal axis of the rotor. The slot 202 may also be offset relative to the longitudinal axis of the rotor. A longitudinal member, such as a piece of wire 204 in the illustrated embodiment, may be provided extending through the slot 202. During rotation, the range of motion of the rotor may be restricted by the edges 207, 209 and 216, 218 of the slot 202 in the tail cap 200 contacting the wire 204.

The range of motion of the rotor may be a function of the combined characteristics of the tail cap 200 and the longitudinal member 206. For example, a larger ratio of the width of the slot 202 the thickness or diameter of the longitudinal member 206 may provide a greater range of motion of the rotor. Similarly, a larger diameter tail cap 200, i.e., a longer slot 202, may provide a smaller range of motion of the rotor. These various characteristics may be varied relative to one another to achieve a desired maximum range of motion of the rotor.

According to one embodiment of the mechanical stop system disclosed herein, the wire 204, or longitudinal member, extending through the slot 202 may be provided in a fixed location relative to the tail cap 200, thereby providing a fixed range of motion. Alternatively, the range of motion provided by the mechanical stop may be at least partially adjustable. As in the illustrated embodiment, the wire 204 may be fixed at a first end 206 and adjustable at the second end 208. The first end 206 may be maintained in fixed position by securing the end 206 to a portion of the galvanometer housing, etc. (not shown in the illustrated embodiment), for example using a set screw 220 or similar feature. In other embodiments, the first end 206 of the longitudinal member 204 may welded or bonded to stationary component of the galvanometer, or disposed in a notch or hole, with or without the use of an adhesive, etc.

The second, adjustable, end 208 of the wire 204 may be movable transverse to the longitudinal axis of the rotor. That is, the adjustable end of the wire 208 may be moveable in a plane normal to the longitudinal axis of the rotor. Being movable transverse to the longitudinal axis of the rotor, as used herein, does not preclude movement in other directions as well. In the embodiment shown in FIG. 4 the adjustable end 208 of the wire 204 is shown captured between two set screws 212, 214. The adjustable end 208 of the wire 204 may be moved by translating the screws 212, 214, wherein translating said screws means loosening or tightening the screws. For example, the adjustable end 208 may be moved loosening one screw, e.g. 212, and tightening the other screw 214. Accordingly, the adjustable end 208 of the wire 204 may be moved in the direction of the screw that was loosened, 212, in the foregoing example. Using set screws 212, 214 in this manner may allow very fine and/or precise adjustments of the second end 208 of the wire 204 to be easily accomplished.

Other embodiments that may allow adjustment of an end a longitudinal member, such as the end of a wire, may also be employed in embodiments consistent with the present disclosure. For example, the adjustable end of the wire may be captured on one side by a set screw, as in the illustrated embodiment, and by a spring on the other side. In such an embodiment, if the screw is tightened the spring may be compressed and the end of the wire captured between the screw and the spring may be moved in the direction of the spring. Conversely, if the screw is loosened, the spring may expand and drive the end of the wire toward the loosened screw. Numerous other configurations for moving an end of the wire are possible within the scope of this disclosure.

Adjusting only the second end 208 of the wire 204 may bend the wire 204 into an arc or curve extending from the fixation point of the other end 206 of the wire 204. Accordingly, adjusting the wire 204 in the foregoing manner may adjust the amplitude, or range of motion, in one direction of rotation of the rotor. For example, in the embodiment illustrated in FIG. 4, if the wire 204 is in a neutral position, that is the wire 204 extends in a generally straight line and has not been biased or moved to one side or the other, when the rotor, and therefore the tail cap 200, rotates in a counterclockwise direction in the illustrated view the range of rotation of the rotor will be restricted when the diagonally opposed edges 209 and 218 of the tail cap 200 contact the wire 204. During clockwise rotation, the range of motion of the rotor may be restricted by the diagonally opposed edges 207, 216 of the tail cap 200 contacting the wire 204.

In one embodiment, moving the adjustable end 208 of the wire toward the set screw 214 curve the wire 204 toward the set screw 214, and may exhibit a greater displacement from a neutral condition adjacent the adjustable end 208 as compared to the fixed end 206. When the rotor, and therefore the tail cap 200, is rotated in a counterclockwise direction, the range of rotation of the rotor will be restricted by contact between the edge 209 of the tail cap 200 and the wire 204. When the rotor, and therefore the tail cap 200, is rotated in the clockwise direction the range of motion of the rotor will be restricted by contact between the edge 216 of the tail cap 200 and the wire 204. Contact between the edge 216 and the wire may occur before contact between the edge 207 of the tail cap and the wire 204. The range and location of motion of the tail cap 200, and therefore the range of motion of the rotor, will be accordingly shifted and restricted.

According to other embodiments consistent with the present disclosure, the position of each end of the longitudinal member may be adjustable. According to one embodiment, both ends of the longitudinal member may be adjustable together. For example, a displacement of a first end of the longitudinal member in a clockwise direction may produce an equal displacement of a second end of the longitudinal member also in a clockwise direction. In such an embodiment, the range of motion is not reduced or enlarged, but the relative location of the range of motion may be moved, for example, relative to a fixed location on the galvanometer housing.

In a further embodiment each end of the longitudinal member may be independently moveable. According to such an embodiment, both the range of motion of the rotor and the relative location of the rotation may be independently adjusted. According to one specific embodiment similar to the embodiment shown in FIG. 4, rather than fixing the first end 206 of the wire with the set screw 210, the first end of the wire may be captured between the set screw 210 and a second opposing set screw (not shown) in a manner similar to the capture of the second end 208 of the wire 204 between the two set screws 212, 214. In such an embodiment, the first end 206 of the wire 204 may be adjusted in the same manner as the second end 208, that is, by loosening one set screw and tightening the other.

In the illustrated embodiment, the mechanical stop arrangement is located on the tail shaft of the rotor. Accordingly, the adjustment for the mechanical stop may be carried out from a rear portion of the galvanometer assembly or housing. Adjusting the mechanical stop from a rear portion of the galvanometer may allow easy access to the adjustment mechanism. For example, it may be possible to adjust the mechanical stops consistent with the present disclosure even when the galvanometer is installed in a scanning head or other assembly. Accessing and adjusting the mechanical stops may, therefore, be possible during testing. Because the mechanical stops may be adjusted from the rear of the galvanometer, the stops may be adjusted without interfering with a beam of light being projected through a scanning head, or other assembly, including the galvanometer and without having to first remove the galvanometer from the assembly.

Consistent with further embodiments, adjustment of the mechanical stops may be accomplished from the exterior of the galvanometer housing. For example, the galvanometer housing may include openings or ports that may allow the set screws shown in the illustrated embodiment to be accessed from outside the galvanometer. Similar access features may also be employed with embodiments including adjustment features other than set screws. Access features, while not necessary, may further increase the easy with which the mechanical stops may be adjusted.

According to the illustrated embodiment, the slot 202 of the mechanical stop arrangement may be defined in a in a tail cap 200 that may be either directly or indirectly coupled to the tail shaft 106 of the galvanometer rotor. For example, the tail cap 200 may include a coupling and may be bonded to the tail shaft of the rotor. According to an alternative embodiment, the slot may be defined in tail shaft itself. According to either embodiment, the moving portion of the mechanical stop, such as the tail cap 200 in the illustrated embodiment, need not include any radially extending features and may be relatively compact to minimize the inertia added by, or associated with, the mechanical stop. Accordingly, a mechanical stop may be provided that does not, or at least minimally, adversely affect the performance of the galvanometer. Additionally, using a tail cap 200 coupled to the tail shaft 106, or providing a slot in the tail shaft itself, may be achieved without weakening the shaft or rotor, for example by bonding the tail cap to the shaft rather than drilling a hole through the shaft or rotor.

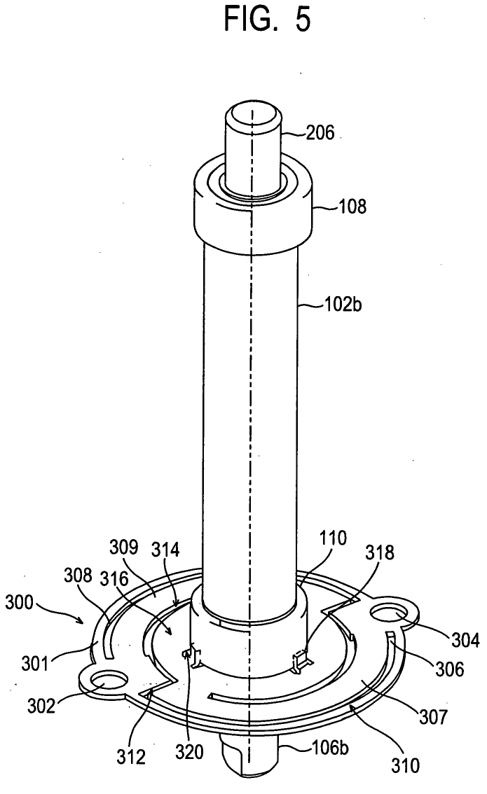

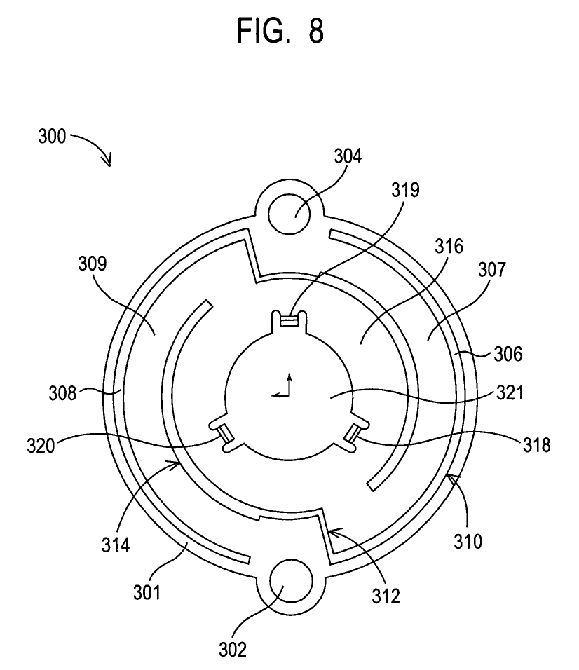

Referring to FIG. 5, a galvanometer rotor 102b is shown in perspective view, including an output shaft 20b and a tail shaft 106b extending from opposed ends of the rotor 102b. Top and bottom bearings 108, 110 may be carried on the output shaft 20b and tail shaft 106b respectively. A diaphragm spring 300 may be provided to preload the bearing 110 associated with the tail shaft 106b. The embodiment of the diaphragm spring 300 of FIG. 5 is illustrated in plan view in FIG. 8. As used in any embodiment herein, a diaphragm spring is base member including a portion of the base that is resiliently displaceable on an axis generally normal to the base. In the illustrated embodiment, the diaphragm spring is a generally planar member and the central portion is displaceable in a direction generally normal to the planar member. However, it will be appreciated that he diaphragm spring may be contoured or arcuate.

The illustrated diaphragm spring 300 is shown generally configured as a round disc including mounting screw holes 302, 304 that may be spaced around the perimeter of a mounting face 301 of the spring 300. The mounting face 301 may be configured to mate with a mounting surface on a galvanometer housing, chassis, substructure, etc. for retaining the bearing 110 in a desired placement or configuration. The spring 300 may include cutouts 306, 308, generally defining slots in the illustrated embodiment. The cutouts 306, 308 in turn define resilient members 307 and 309. In the illustrated embodiment, the cutouts 306, 308 are provided having a stepped-spiral configuration. That is, the cutouts define a pattern of intermittently decreasing diameter, or a diameter decreasing at varying rates. For example, cutout 306 is shown including a first arcuate portion 310 having a generally uniform diameter. The cutout 306 then steps generally radially inwardly 312, and includes a second arcuate portion 314 having a generally uniform diameter. The diameter of the second arcuate portion 314 is less than the diameter of the first arcuate portion 310. The second cutout 308 is shown similarly configured and angularly shifted from the first cutout 306. It will be understood that the number of cutouts, the number of steps and the number of resilient members may be varied within the scope of the present disclosure.

The stepped-spiral configuration of the cutouts 306, 308 described above may allow a central portion 316 of the diaphragm spring 300 resiliently travel along an axis generally normal to the spring 300, e.g. through the resilient deformation of resilient members 307, 309. Additionally, the stepped-spiral cutout pattern may restrict rotation of the central portion 316 as well as radial deflection of the central portion 316. Configurations of cutout patterns or slots other than the depicted configuration may suitably be employed to allow a portion of the diaphragm spring to resiliently travel along an axis generally normal to the spring. For example, rather than a stepped-spiral configuration a non-stepped spiral cutout pattern, i.e. a spiral pattern having a continuously decreasing diameter, may be employed. Other variations are also possible consistent with the present disclosure. Additionally, it is not necessary for the diaphragm spring to have a circular shape. Other curved or polygonal shapes may suitably be employed to provide a diaphragm spring consistent with the present disclosure. As with a circular diaphragm spring, such alternative configuration may employ a variety of cutout patterns, including linear or curved cutout patterns, and cutout patterns including linear and curved features. Additionally, it is not necessary for the diaphragm spring to assume a completely flat configuration in an unstressed state. For example, a central portion of the diaphragm spring may project from the diaphragm spring. Additionally, the diaphragm spring may have an arced or contoured shape when it is in an unstressed condition.

As shown in FIGS. 5 and 8, the diaphragm spring 300 may include upstanding tabs, e.g. 318, 319, 320 visible in the illustration. The tabs 318, 319, 320 may be arranged to locate the bearing 110 relative to the spring 300. The tabs 318, 319, 320 may retain the bearing 110 in a radial direction relative to the spring 300. This configuration may reduce or eliminate radial movement of the bearing 110 and, thereby, reduce or eliminate wobble in the rotor 102. Numerous alternative features may be used to locate the bearing relative to the spring and to reduce or eliminate radial movement of the bearing. Additionally, the tabs 318, 319, 320 may also retain the bearing 110 seated against the central portion 316. Retaining the bearing 110 to the central portion 316 of the diaphragm spring 300 may facilitate assembly of the galvanometer by allowing the spring 300 and bearing 110 to be installed as a unit or subassembly. As also shown, the diaphragm spring 300 may include an opening 321 in the central portion 316. The opening 321 may permit the tail shaft 106b of the rotor 102b to pass through the spring 300.

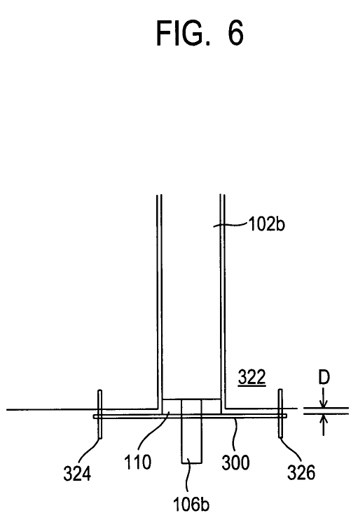

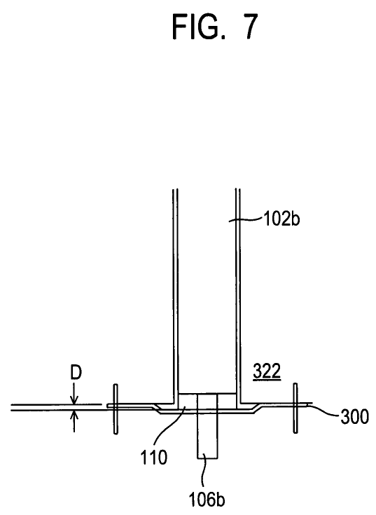

Referring to FIG. 6, in use, the diaphragm spring 300 may provide a bearing preload by positioning the diaphragm spring 300 on the bearing 110 and installing the diaphragm spring 300 to a mounting structure 322 of the galvanometer, e.g. using screws 324, 326 extending through screw holes 302, 304, or otherwise securing the diaphragm spring 300 to the mounting structure. As shown in FIG. 6, the bearing 110 may protrude a predetermined distance D beyond the mounting structure 322 for the diaphragm spring 300. Accordingly, when the diaphragm spring 300 is secured to the mounting structure 322, as shown in FIG. 7, the central portion 316 of the diaphragm spring 300 may be caused to resiliently deflect the distance D. The amount of preload provided by the diaphragm spring 300 may be, therefore, proportional to the spring constant of the diaphragm spring 300 and the distance D that the central portion 316 of the diaphragm spring 300 is displaced when the diaphragm spring 300 is installed.

As used in the foregoing description, spring constant is the ratio of force applied to the central portion 316 relative to the deformation of the center portion relative to the mounting surface 301 of the diaphragm spring produced by that force. The spring constant may be a function of a variety of physical, as well as design characteristics of the diaphragm spring. For example, the type of material from which the diaphragm spring is formed as well as the thickness, width, and effective length of the resilient members may all affect the spring constant of the diaphragm spring. Various other factors may also affect the spring constant of the diaphragm spring and/or the bearing preload.

A diaphragm spring consistent with the present disclosure may simplify the assembly of a galvanometer. As discussed above, the desired bearing preload is determined by the spring constant of the diaphragm spring, the configuration of the cutouts, and the amount of deflection experienced by the spring. These factors may be controlled to achieve a predetermined bearing preload. Installing the diaphragm spring on the bearing in the above-described manner achieves the predetermined bearing preload without the need for adjustment during assembly, e.g. by adjusting the torque and a bearing retainer. Eliminating the need to adjust the bearing preload during assembly may reduce the assembly time of a galvanometer utilizing a diaphragm spring consistent with the present disclosure. Furthermore, the diaphragm spring herein presents a relatively low profile and may reduce the volume in the galvanometer housing required for the rear bearing assembly. This may allow the overall size of the galvanometer to be reduced.

It should be understood that the various specific embodiments of this disclosure have been presented for the purpose of illustration only and should not be construed as limiting the scope of the claimed subject matter. Additionally, it should be understood that the various features and aspects described in the present disclosure may be susceptible to use alone or in various combinations with one another.

1. A galvanometer comprising:
a rotor comprising a cylindrical magnet having a first opening extending inwardly from a first end of said magnet;
a shaft at least partially received in said opening, said shaft extending from said magnet.

2. A galvanometer according to claim 1 further comprising a bearing said bearing carried on said shaft.

3. A galvanometer according to claim 1 wherein said shaft comprises an output shaft of said galvanometer.

4. A galvanometer according to claim 1 wherein said shaft comprises a tail shaft.

5. A galvanometer according to claim 1 said magnet comprising a second opening extending inward from a second end of said magnet, and a second shaft at least partially received in said second opening and extending from said magnet.

6. A galvanometer according to claim 1 wherein said shaft comprises a ceramic material.

7. A galvanometer according to claim 1 wherein said shaft comprises a metallic material.

8. A galvanometer according to claim 1 wherein said shaft comprises a composite material.

9. A galvanometer according to claim 1 wherein said shaft is bonded in said opening.

10. A galvanometer comprising:
a rotor comprising a tail shaft, said tail shaft comprising a tail cap, said tail cap comprising a slot extending into an end of said tail cap;
a longitudinal member extending through said slot.

11. A galvanometer according to claim 10 wherein said tail cap comprises a member coupled to said tail shaft.

12. A galvanometer according to claim 10 wherein a first end of said longitudinal member is movable transverse to a longitudinal axis of said rotor.

13. A galvanometer according to claim 12 comprising a threaded member bearing on said first end of said longitudinal member, said longitudinal member being adjustable by translating said screw.

14. A galvanometer according to claim 10 wherein a second end of said longitudinal member is fixed.

15. A galvanometer according to claim 14 wherein said second end of said longitudinal member is disposed in a hole.

16. A galvanometer according to claim 14 wherein said second end of said longitudinal member is fixed by a screw.

17. A galvanometer according to claim 12 wherein a second end of said longitudinal member is movable transverse to a longitudinal axis of said rotor.

18. A galvanometer according to claim 10 wherein said longitudinal member comprises a wire.

19. A galvanometer comprising:
a rotor comprising a tail shaft;
a bearing received on at least a portion of said tail shaft; and
a diaphragm spring engaged with said bearing, said diaphragm spring providing a predetermined axial force on said bearing.

20. A galvanometer according to claim 19 wherein said diaphragm spring comprises a member wherein a portion of said member is resiliently displaceable in a direction generally normal to said member.

21. A galvanometer according to claim 20 wherein said diaphragm spring comprises a planar member wherein a portion of said planar member is resiliently displaceable generally normal to said planar member.

22. A galvanometer according to claim 20 wherein said diaphragm spring comprises generally a circular disc wherein a center portion of said disc is resiliently normal to said disc.

23. A galvanometer according to claim 22 wherein said diaphragm spring comprise a cutout defining a generally spiral slot in said disc.

24. A galvanometer according to claim 22 wherein said diaphragm spring comprises a plurality of cutouts each defining a stepped spiral slot in said disc.

25. A galvanometer according to claim 19 wherein said diaphragm spring comprises a feature engageable with said bearing.

26. A galvanometer according to claim 25 wherein said diaphragm spring comprises a plurality of upstanding tabs engageable with said bearing.

27. A scanning system comprising:
a galvanometer comprising a rotor comprising a cylindrical magnet including a first opening in a first end thereof, and a shaft at least partially received in said first opening and extending from said magnet; and
an optical element coupled to said rotor, said optical element rotatably positionable by movement of said rotor.

28. A scanning system according to claim 27 wherein said optical element is directly coupled to said rotor by an output shaft.

29. A scanning system according to claim 27 wherein said shaft comprises an output shaft and said optical element is coupled to said output shaft.

30. A scanning system according to claim 27 said rotor including a second opening in a second end thereof and a second shaft at least partially received in said second opening and extending from said magnet.

31. A scanning system comprising:
a galvanometer comprising a rotor having a tail shaft comprising a tail cap having a slot therein, and a longitudinal member extending through said slot; and
an optical element coupled to said rotor, a rotational range of motion of said optical element controlled by said longitudinal member extending through said slot.

32. A scanning system according to claim 31 wherein said tail cap comprises a member coupled to said tail shaft.

33. A scanning system according to claim 31 wherein a first end of said longitudinal member is movable transverse to a longitudinal axis of said rotor.

34. A scanning system according to claim 33, wherein said range of motion of said optical element is varied by moving said first end of said longitudinal member.

35. A scanning system according to claim 31 wherein said optical element is directly coupled to said rotor.

36. A scanning system comprising:
a galvanometer comprising a rotor having a tail shaft with a bearing received on said tail shaft, and a diaphragm spring engaged with said bearing, said diaphragm spring providing a predetermined axial force on said bearing; and
an optical element coupled to said rotor.

37. A scanning system according to claim 36 wherein said diaphragm spring comprises a member wherein a portion of said member is resiliently displaceable in a direction generally normal to said member.

38. A scanning system according to claim 36 wherein said optical element is directly coupled to said rotor.

39. A scanning system according to claim 36 wherein said diaphragm spring comprises a disc having at least one spiral cutout.

40. A scanning system according to claim 36 wherein said spiral cutout comprises a stepped-spiral cutout.
